(19) United States
(12) Patent Application Publication
(10) Pub. No.: US 2014/0129898 A1
(43) Pub. Date: May 8, 2014

(54) EVALUATION OF PERFORMANCE CHARACTERISTICS OF A READ CHANNEL

(71) Applicant: LSI Corporation, San Jose, CA (US)

(72) Inventors: Aleksey Alexandrovich Letunovskiy, Tokarevka (RU); Nikola Ilyich Radovanovic, Los Altos, CA (US); Pavel Aleksandrovich Aliseychik, Moscow (RU); Denis Vladimirovich Zaytsev, Moscow (RU); Alexander Nikolaevich Filippov, Moscow (RU)

(21) Appl. No.: 13/914,035

(22) Filed: Jun. 10, 2013

(30) Foreign Application Priority Data
Nov. 7, 2012 (RU) 2012147471

(51) Int. Cl. H03M 13/29

(52) U.S. Cl. CPC H03M 13/296
USPC 714/755

(57) ABSTRACT

A machine-based method for modifying a parity-check matrix in a manner that controllably and quantifiably raises the corresponding error-floor level and/or rate of miscorrection to make these quantities observable in direct read-channel simulations that can be completed in a relatively short amount of time. In one embodiment, the method is used to compare different turbo-decoding schemes by comparing the read-channel performance characteristics corresponding to a modified matrix, instead of the original parity-check matrix. In another embodiment, the method is used to validate a heuristic error-rate estimation tool. After being validated, the heuristic error-rate estimation tool can advantageously be used to obtain, in a relatively short amount of time, relatively accurate estimates of the error rates corresponding to the original parity-check matrix.

As used in the relevant art, the term “read channel” refers to the circuitry that performs processing and decoding, such as turbo decoding, of the signals generated by a sensor, such as a magnetic read head, when accessing a corresponding storage medium, such as a magnetic disk platter. A read channel is typically implemented using one or more VLSI circuits. The development, design, simulation, refinement, and testing of a read-channel chip usually involves evaluation of a relatively large number of different turbo-decoders, e.g., based on their respective sector-failure rates (SFRs), bit-error rates (BERs), or other suitable performance measures.

In modern data-storage systems, error rates can be extremely low, such as 10⁻¹⁵ or lower, in terms of the BER. At these error rates, meaningful characterization of the read channel with conventional design and simulation tools might include a relatively large number of simulations and/or relatively long simulation runs, which can take from several weeks to several months to complete even on multiprocessor clusters. More-practical (e.g., faster) means for evaluating error-rate characteristics of the read channel are therefore desirable.

At least some of the above-indicated problems are addressed by various embodiments of a machine-based method for modifying a parity-check matrix in a manner that controllably and quantifiably raises the corresponding error-floor level and/or rate of miscorrection to make these quantities observable in direct read-channel simulations that can be completed in a relatively short amount of time. In one embodiment, the method is used to compare different turbo-decoding schemes by comparing the read-channel performance characteristics corresponding to a modified matrix, instead of the original parity-check matrix. In another embodiment, the method is used to validate a heuristic error-rate estimation tool. After being validated, the heuristic error-rate estimation tool can be used to obtain, in a relatively short amount of time, relatively accurate estimates of the error rates corresponding to the original parity-check matrix.

Some of the disclosed embodiments include (i) integrated circuits fabricated based on the read-channel evaluation results obtained using the above-mentioned method for modifying a parity-check matrix and/or (ii) non-transitory machine-readable media, having encoded thereon program code, wherein, when the program code is executed by a machine, the machine implements the above-mentioned method for modifying a parity-check matrix and/or the above-mentioned heuristic error-rate estimation tool.

Other embodiments of the invention will become more fully apparent from the following detailed description and the accompanying drawings, in which:

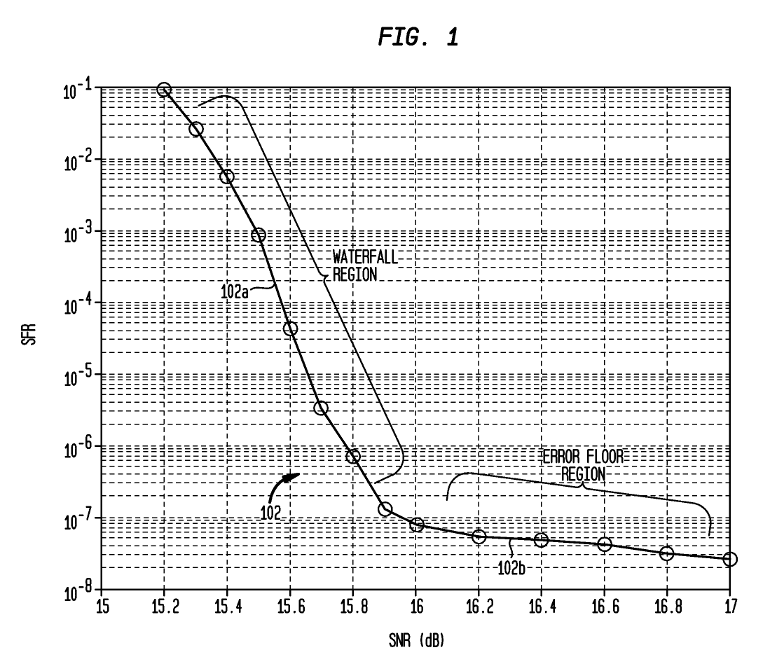

FIG. 1 graphically shows an exemplary dependence of the sector-failure rate on the signal-to-noise ratio that can be used to evaluate error-rate characteristics of a turbo decoder according to an embodiment of the disclosure;

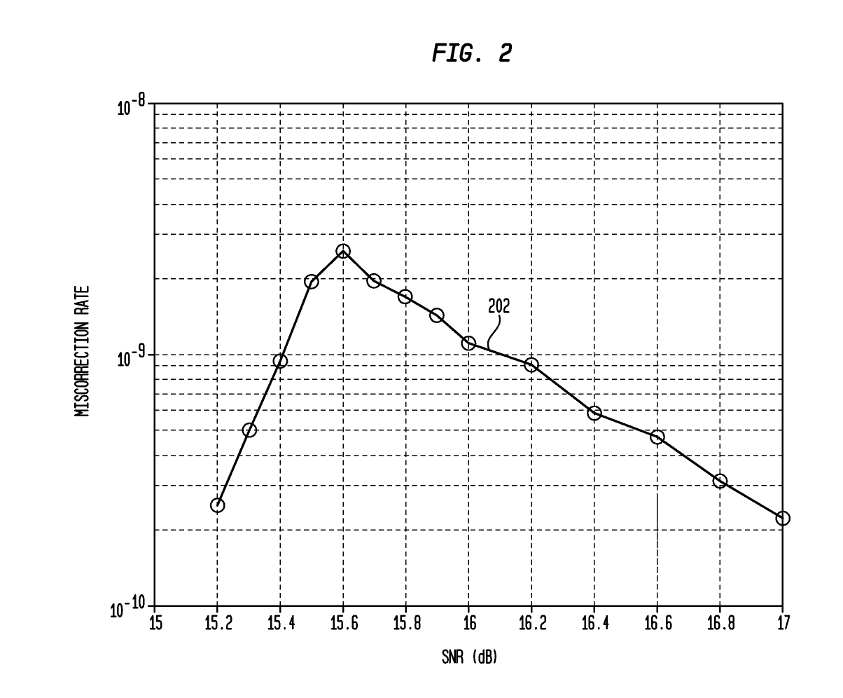

FIG. 2 graphically shows an exemplary dependence of the rate of miscorrection on the signal-to-noise ratio that can be used to evaluate error-rate characteristics of a turbo decoder according to an embodiment of the disclosure;

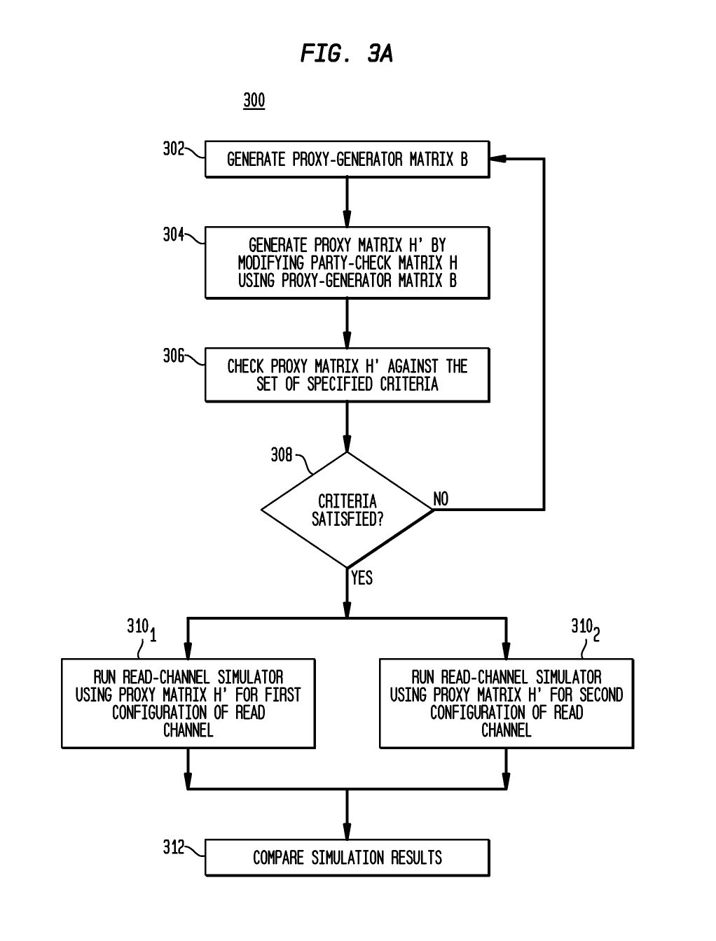

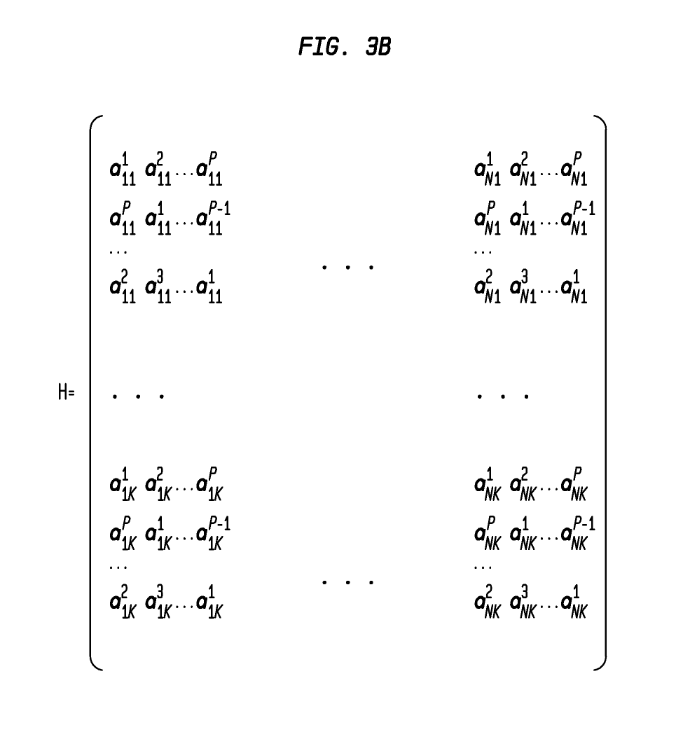

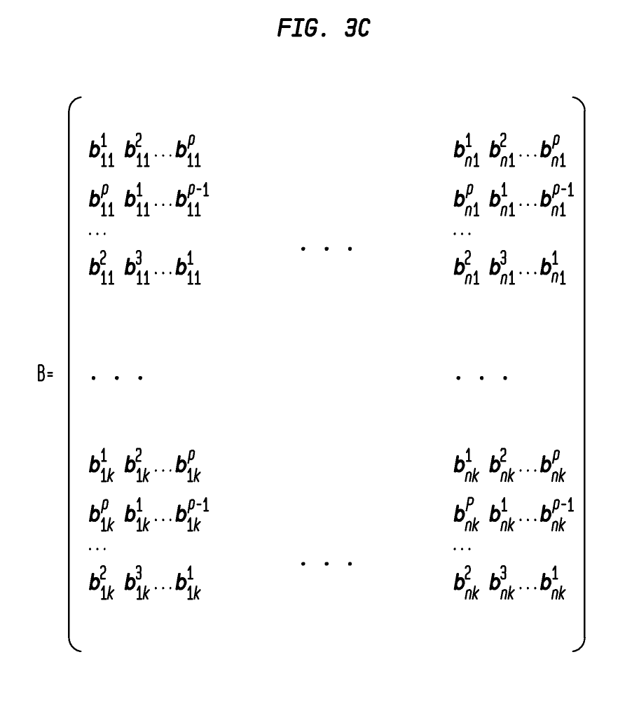

FIGS. 3A-D illustrate a machine-based method of estimating error rates in a read channel according to an embodiment of the disclosure;

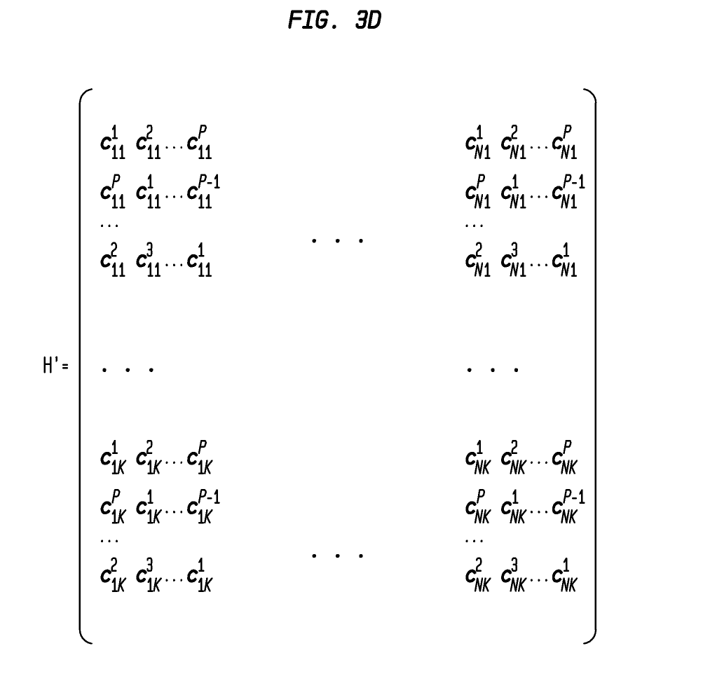

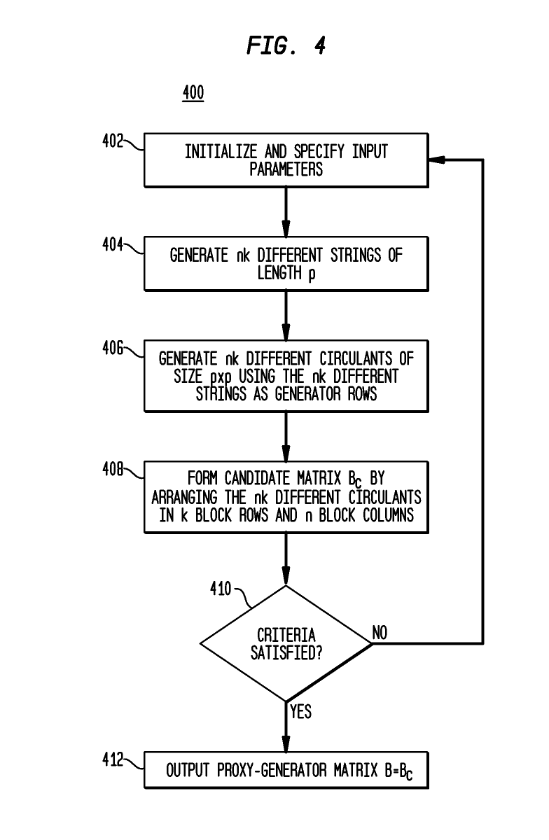

FIG. 4 shows a flowchart of a method of generating a proxy-generator matrix that can be used in the method of FIG. 3 according to an embodiment of the disclosure;

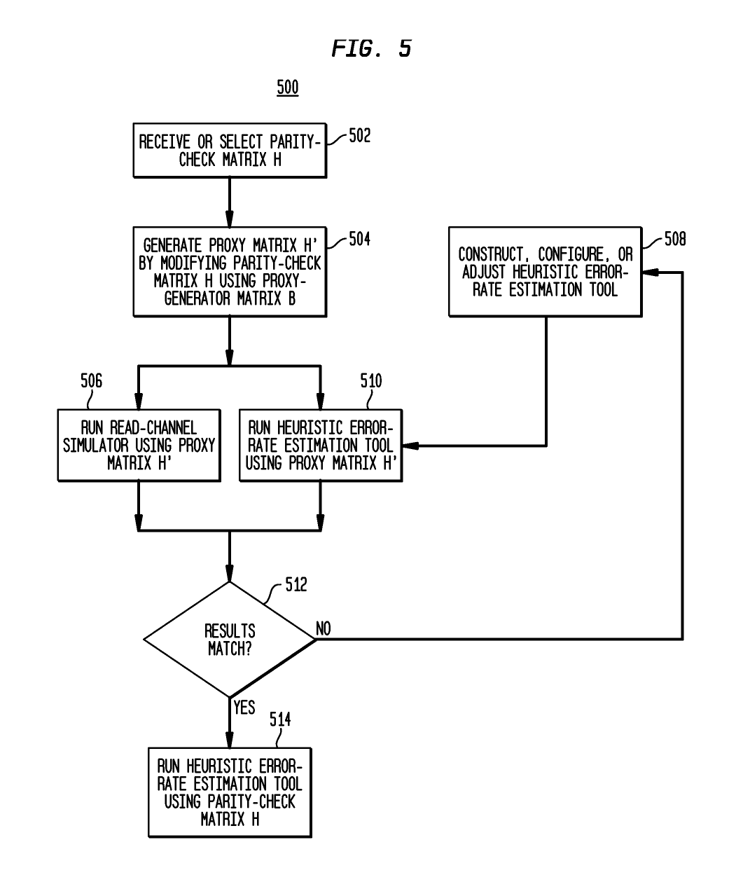

FIG. 5 shows a flowchart of a machine-based method of estimating error rates in a read channel according to an embodiment of the disclosure; and

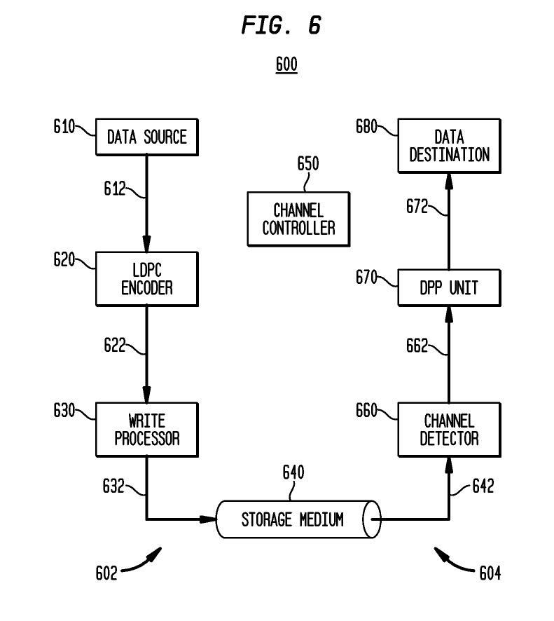

FIG. 6 shows a block diagram of a communication system having a read channel that can be designed in accordance with an embodiment of the disclosure.

The following acronyms/abbreviations are used in the description of embodiments and/or in the accompanying drawings:

ASIC Application-Specific Integrated Circuit;

BER Bit-Error Rate;

DPP Decoding and Post-Processing;

DSP Digital Signal Processor;

FPGA Field-Programmable Gate Array;

LDPC Low-Density Parity Check;

LLR Log-Likelihood Ratio;

MAP Maximum A Posteriori;

RLL RunLength Limited;

SFR Sector-Failure Rate;

SNR Signal-to-Noise Ratio;

SPA Sum Product Algorithm;

VLSI Very-Large-Scale Integration.

FIG. 1 graphically shows an exemplary SFR-versus-SNR curve 102 that can be used to evaluate error-rate characteristics of a turbo decoder, such as an LDPC decoder, according to an embodiment of the disclosure. Curve 102 comprises two portions, labeled 102a and 102b and referred to as the waterfall region and the error-floor region, respectively. Waterfall region 102a is characterized by a relatively large negative value of the slope, which reflects the fact that, in this region, the SFR decreases relatively quickly as the SNR increases. Error-floor region 102b is characterized by a relatively small negative value of the slope, which reflects the fact that, in this region, the SFR decreases relatively slowly as the SNR increases. In the example shown in FIG. 1, the transition between waterfall region 102a and error-floor region 102b occurs at an SNR value of about 15.9 dB.

Performance of different turbo decoders can be compared in a relatively straightforward manner by comparing their SFR-versus-SNR curves, analogous to curve 102, when these curves are available. For example, decoder 1 might be considered to be a better decoder than decoder 2, when (i) the waterfall region of the SFR-versus-SNR curve corresponding to decoder 1 is located to the left of the waterfall region of the SFR-versus-SNR curve corresponding to decoder 2 and (ii) the error-floor region of the SFR-versus-SNR curve corresponding to decoder 1 is located below the error-floor region of the SFR-versus-SNR curve corresponding to decoder 2. One problem however is that, while the waterfall part of the SFR-versus-SNR curve can sometimes be estimated relatively accurately by means of direct simulation in software or using a hardware simulator (such as a field-programmable gate array, FPGA), the error-floor part of the SFR-versus-SNR curve is significantly more difficult to estimate by direct or hardware-based simulation due to a corresponding unreasonably long simulation time, which stems from the very low SFR values in that part of the SFR-versus-SNR curve. Some embodiments disclosed herein are therefore directed at providing means for obtaining a relatively accurate estimate of the error-floor region of the SFR-versus-SNR curve, such as curve 102, in a relatively short amount of time.

FIG. 2 graphically shows an exemplary dependence of the rate of miscorrection on the SNR for a turbo decoder, such as an LDPC decoder, which dependence can be used to evaluate error-rate characteristics of the turbo decoder according to an embodiment of the disclosure. As used herein, the term “miscorrection” refers to an event in which a noisy read signal received by the decoder from the channel detector is decoded to produce a valid codeword, which nevertheless is not the correct codeword. Since the parity checks are satisfied for any valid codeword and their satisfaction is used in the decoder as a trigger for terminating the corresponding decoding processing, the decoder itself cannot recognize a miscorrection event, which causes a decoding error. A miscorrection curve 202 shown in FIG. 2 illustrates a dependence of the rate of miscorrection on the SNR observed for a representative LDPC decoder. It is worth noting that curve 202 has a well-pronounced maximum located at an SNR value of about 15.6 dB.

Fidelity of different turbo decoders can be compared in a relatively straightforward manner by comparing their miscorrection curves, analogous to curve 202, when these curves are available. For example, decoder 1 might be considered to be a decoder of better fidelity than decoder 2 when the miscorrection curve corresponding to decoder 1 is located below the miscorrection curve corresponding to decoder 2. One problem however is that, for the reasons similar to those explained above in reference to the error-floor part of SFR-versus-SNR curve 102 (FIG. 1), the miscorrection curve of a decoder is relatively difficult to estimate by direct or hardware-based simulation. Some embodiments disclosed herein are therefore directed at providing means for obtaining a relatively accurate estimate of the miscorrection curve, such as curve 202, in a relatively short amount of time.

FIGS. 3A-D illustrate a machine-based (e.g., computer-aided) method 300 of estimating performance (e.g., error-rate) characteristics of a read channel according to an embodiment of the disclosure. More specifically, FIG. 3A shows a flowchart of method 300. FIGS. 3B-3D show various matrices that are used or generated at different processing steps of method 300.

Method 300 can, for example, be implemented as an add-on or plug-in module for a more-general computer-aided design and simulation tool. Method 300 can be embodied in the form of program code, stored in a non-transitory computer-readable storage medium such that, when the program code is loaded into and executed by a computer, the computer becomes an apparatus for carrying out method 300. Some examples of read-channel simulators in which various embodiments of method 300 can be used are disclosed, e.g., in Russian Patent Application Serial Nos. 2012135285 (filed on Aug. 16, 2012) and 2012139074 (filed on Sep. 12, 2012), both of which are incorporated herein by reference in their entirety. In one embodiment, method 300 is directed at comparing performance characteristics of two different turbo-decoding schemes. However, not all embodiments of method 300 are so limited. For example, from the provided description, one of ordinary skill in the art will readily understand how to modify the described embodiments of method 300 to produce an embodiment capable of comparing performance characteristics of three or more different turbo-decoding schemes. Method 300 can advantageously be used, e.g., for evaluating the SFR and rate of miscorrection as functions of SNR for a read-channel architecture proposed by the read-channel developer before implementing that architecture in an actual physical VLSI chip.

In one embodiment, method 300 is applied to quasi-cyclic LDPC codes, for which the parity-check matrix, H, can generally be represented as a rectangular array of circulants, for example, as follows:

$$H = ⌊ \begin{matrix}{A}_{11} & … & {A}_{N 1} \\ … & & … \\ {A}_{1 K} & … & {A}_{NK}\end{matrix} ⌋ \qquad ( 1 )$$

where each circulant A_{cr} has a size of PxP (where column index c can be 1, 2, . . . , N and row index r can be 1, 2, . . . , K); N is the number of circulants in a block row of H; K is the number of circulants in a block column of H; and P is the number of matrix elements in each row and each column of each circulant A_{cr}.

In one embodiment, a circulant is a matrix in which each row is a right cyclic-shift of the row above it, and the first row is the right cyclic-shift of the last row. Furthermore, each column is a downward cyclic-shift of the column on its left, and the first column is the downward cyclic-shift of the last column. The top row (or the leftmost column) of a circulant is referred to as the generator row (column) of the circulant. The set of columns of a circulant, read from bottom to top (or from top to bottom), is the same as the set of rows of that circulant, read from left to right (or from right to left). Therefore, the rows and columns of a circulant have the same weight.

In an alternative embodiment, left cyclic shifts in the rows (upward cyclic shifts in the columns) can similarly be used to form a circulant from the generator row (column).

FIG. 3B shows a more-detailed structure of the circulants in quasi-cyclic parity-check matrix H. Note also that each circulant A_{cr} in H may have a different respective generator row (or column). In each generator row, only one of the elements has a value of “one,” while all other elements are “zeros.” Therefore, each row and column of any circulant A_{cr} in H has a weight value of one. When P is a relatively large number, this property of circulants A_{cr} makes parity-check matrix H a sparse (i.e., low density) matrix.

A good quasi-cyclic parity-check matrix that is suitable for use as parity-check matrix H in the LDPC decoder of a practical read channel is usually characterized by (i) an SFR-versus-SNR curve that has a very steep waterfall region and a very low error-floor level and (ii) a very low rate of miscorrection. These characteristics of parity-check matrix H make it very difficult to obtain, by direct (e.g., Monte Carlo) simulation, usable quantitative estimates of the error-floor level and/or rate of miscorrection corresponding to relatively high SNR values typical for modern read channels. In other words, these characteristics of parity-check matrix H make its error-floor level and/or rate of miscorrection practically unobservable in direct simulations carried out over a reasonable period of time, thereby rendering the use of direct simulations unpractical.

Method 300 addresses this problem by relying on a specially constructed proxy matrix H′ that is generated by modifying the original parity-check matrix H in a manner that controllably and quantifiably raises its error-floor level and/or the rate of miscorrection to make these quantities observable, with a read-channel simulator, in simulations that take a relatively short amount of time to complete. Comparison of two different turbo-decoding schemes can therefore be performed by calculating and comparing the performance characteristics corresponding to proxy matrix H′, e.g., as further described below in reference to FIGS. 3A-3D. Possible additional uses of proxy matrix H′ are described in reference to method 500 and FIG. 5.

To controllably and quantifiably raise the error-floor level and/or the rate of miscorrection of parity-check matrix H, a proxy-generator matrix (B) is generated (with B having a smaller size than the size of parity-check matrix H and also having a known set of trapping sets that meet specified criteria) and then used to modify parity-check matrix H. The modification converts parity-check matrix H into proxy matrix H′ in a manner that (i) causes said known trapping sets of proxy-generator matrix B to now become trapping sets of proxy matrix H′ and (ii) causes proxy matrix H′ to also retain most of the dominant trapping sets of parity-check matrix H. The additional trapping sets cause proxy matrix H′ to have a higher error-floor level and/or a higher rate of miscorrection than those of parity-check matrix H, which makes these quantities observable in a relatively short direct simulation of the read channel, wherein the simulated turbo decoder is configured to use proxy matrix H′ for performing parity checks. Due to the way proxy matrix H′ is constructed, the observed error-floor level and rate of miscorrection have quantifiable contributions from the decoding errors caused by dominant trapping sets of the original parity-check matrix H (which trapping sets have mostly been retained in proxy matrix H′). Based on the latter fact, simulation results corresponding to proxy matrix H′ can be used to make meaningful quantitative and/or qualitative predictions about the performance of the read channel, wherein the turbo decoder is configured to use parity-check matrix H for performing parity checks. This general methodology is applied not only in method 300 (FIGS. 3A-3D), but also in method 400 (FIG. 4) and method 500 (FIG. 5).

Referring now to FIG. 3A, method 300 begins at step 302, where proxy-generator matrix B is generated. In one embodiment, proxy-generator matrix B is a relatively small quasi-cyclic matrix comprising a rectangular array of circulants β_{σρ}, as shown in Eq. (2):

$$B = ⌊ \begin{matrix}{β}_{11} & … & {β}_{n 1} \\ … & & … \\ {β}_{1 k} & … & {β}_{nk}\end{matrix} ⌋ \qquad ( 2 )$$

where each circulant β_{σp} is a p×p circulant (where p<<P, column index σ can be 1, 2, . . . , n and row index ρ can be 1, 2, . . . , k); n is the number of circulants in a block row of B; k is the number of circulants in a block column of B; and p is the number of matrix elements in each row and each column of each circulant β_{σρ}. In one embodiment, n<<N and k=K.

FIG. 3C shows a more-detailed structure of circulants β_{σρ} in proxy-generator matrix B. Each circulant β_{σρ} in B may have a different respective generator row (or column). In each generator row, only one element has a value of “one,” while all other elements are “zeros.” In one embodiment, N=27, K=k=3, P=96, n=7, and p=12.

In one embodiment, step 302 can be implemented using method 400, which is described in more detail below in reference to FIG. 4. Briefly, proxy-generator matrix B generated at step 302 has the following characteristics:
(i) the minimum distance of B is greater than a first threshold value, L₁;
(ii) the number of minimum codewords that B has is smaller than a second threshold value, L₂; and
(iii) the number of minimum near-codewords that B has is smaller than a third threshold value, L₃.
As used herein the term “minimum codeword” refers to a nonzero codeword of B having a minimum weight, where the weight of the codeword refers to the number of “ones” in that codeword. The term “minimum distance of a matrix” refers to the weight of a minimum codeword of that matrix. The term “near-codeword” refers to a stable word, w, for which the weight of wB^{T} is greater than a first specified nonzero value, α₁, but smaller than or equal to a second specified value, α₂, where T denotes transposition. Near-codeword w is stable in the sense that it contains a trapping set from which the given decoder is unable to escape on its own. The term “minimum near-codeword” refers to a near-codeword having a smallest value of the weight of wB^{T}.

If the following parameters are used: L₁=6; L₂=10; L₃=100;α₁=3; and α₂=4, then the third of the three above-listed characteristics can take the following form: (a) B does not have any near-codewords for which the weight of wB^{T} is 1,2, or 3; and (b) B has fewer than 100 near-codewords for which the weight of wB^{T} is 4. Other parameter values are also possible.

At step 304, proxy matrix H′ is constructed for parity-check matrix H using proxy-generator matrix B of step 302 Parity-check matrix H has the general structure described above in reference to Eq. (1) and FIG. 3B.

FIG. 3D shows the general structure of proxy matrix H. The various matrix elements cⱼₘⁱ of H′ are determined based on (i) the corresponding parity-check matrix H and (ii) proxy-generator matrix B of step 302, e.g., by applying a set of rules expressed by the following piece of pseudo-code:

cⱼₘⁱ=bⱼₘⁱ, if i≦p and j≦n (3a)

cⱼₘⁱ=0, if p<i≦P and j≦n (3b)

cⱼₘⁱ=aⱼₘⁱ. else (3c)

(also see FIGS. 3B and 3C).

In effect, Rules (3a)-(3b) tell us that proxy matrix H′ can be generated using the following exemplary steps. First, the generator row of each circulant A_{cr} in the first n block columns of parity-check matrix H is replaced by a respective binary string formed by concatenating the generator row of the corresponding circulant β_{cr} of proxy-generator matrix B (see Eq. (2)) and P-p zeros. Second, in each circulant A_{cr} having a replaced generator row, said generator row is used to generate replacement rows for the next P-1 rows of the circulant. More specifically, each such replacement row is generated by applying a right cyclic shift to the replacement row above it, starting from the row located just below the replaced generator row and ending with the P-th row of the circulant. Circulants Λ_{cr} with the value of index c greater than n remain unchanged. These unchanged circulants are circulants Λ_{n+1,r}, Λ_{n+2,r}, . . . , Λ_{N,y}, where r=1, 2, . . . , K.

At step 306, proxy matrix H constructed at step 304 is checked against a set of specified criteria. For example, one of such criteria can be whether or not the minimum distance of proxy matrix H′ is the same as the minimum distance of the proxy-generator matrix B generated at step 302. Additional criteria may also be used.

Step 308 serves to redirect the subsequent processing of method 300 based on the results of the checks performed at step 306. If proxy matrix H′ satisfies the specified criteria, then the processing of method 300 is directed to steps 310₁ and 310₂. However, if proxy matrix H′ and H₂′ does not satisfy the specified criteria, then the processing of method 300 is directed back to step 302, where a different proxy-generator matrix B is generated. Several different proxy-generator matrices B may have to be tried before the processing of method 300 can continue on to steps 310₁ and 310₂.

At step 310₁, the read-channel simulator corresponding to a first configuration of the read channel is run using proxy matrix H′ in place of parity-check matrix H. Due to the fact that proxy matrix H′ controllably and quantifiably raises the error-floor level and/or the rate of miscorrection of the LDPC decoder, the simulations directed at obtaining these quantities can advantageously be finished in a relatively short amount of time. Exemplary simulation results may look similar to the data shown in FIG. 1 and/or FIG. 2.

At step 310₂, the read-channel simulator corresponding to a second configuration of the read channel is run using proxy matrix H′ in place of parity-check matrix H. Step 310₂ is generally analogous to step 310₁, which enables meaningful and convenient comparison of the simulation results obtained in these steps. Depending on the hardware of the host machine, steps 310₁ and 310₂ may be performed in parallel to one another or in series.

The first and second configurations of the read channel for which the simulations are run at steps 310₁ and 310₂, respectively, may differ from one another, for example, in one or more of the following: (i) the applied decoding scheme; (ii) the type of the decoder (e.g., Repetition Code MAP Decoder, Single-Parity-Check Code MAP Decoder, Gallager SPA Decoder, Box-Plus SPA Decoder, etc); (iii) the general scheme of the read channel (e.g., RLL or no RLL, Viterbi detector, bit-flipping, etc.); and (iv) one or more of adjustable parameters (e.g., the number of global iterations, the number of local iterations; precision of calculations, etc) under the same read-channel architecture. This is a non-exhaustive list, and the first and second configurations of the read channel may also differ in other, non-listed features.

At step 312, the simulation results obtained at steps 310₁ and 310₂ are compared to determine which of the first and second configurations of the read channel has better performance characteristics. If the first configuration has better performance characteristics with proxy matrix H′ than the second configuration, then this result is a strong indication that the first configuration will enable the actual read channel to perform better with parity-check matrix H than the second configuration. Similarly, if the second configuration has better performance characteristics with proxy matrix H′ than the first configuration, then this result is a strong indication that the second configuration will enable the actual read channel to perform better with parity-check matrix H than the first configuration. Based on the comparison performed at step 312, one of the first and second configurations of the read channel may be selected for the actual read channel.

FIG. 4 shows a flowchart of a method 400 of generating a proxy-generator matrix B that can be used to implement step 302 (FIG. 3) according to an embodiment of the disclosure. The general structure of proxy-generator matrix B that is being generated using method 400 is shown in Eq. (2) and FIG. 3C.

Method 400 is initialized at step 402, where appropriate input parameters are specified and a corresponding executable file is loaded into the host processor. The set of input parameters may include, but is not limited to the values of p, n, k, L₁, L₂, L₃, α₁, and α₂. Recall that p is the size of the constituent circulants β_{σρ} in matrix B (also see FIG. 3C); n is the number of circulants in a block row of matrix B (also see Eq. (2)); k is the number of circulants in a block column of matrix B (again see Eq. (2)); L₁ is the threshold value for the minimum distance of B; L₂ is the threshold value for the number of minimum codewords of B; L₃ is the threshold value for the number of minimum near-codewords of B; and α₁ and α₂ define the range of weights for wB^{T}, where w is a near-codeword of B.

At step 404, nk (i.e., n multiplied by k) binary strings are generated, e.g., using a random-number generator. Each of the generated strings is p bits long, with p₁ (<p) of the bits being binary “ones” and the remaining bits being binary “zeros.” For example, the random number generator can be used to determine the positions of the p₁ binary “ones” in each of the nk strings. In one embodiment, p₁=1.

At step 406, nk circulants are generated by: (i) considering each of the nk strings generated at step 404 to be a generator row of a corresponding circulant and (ii) generating each of the nk circulants by applying a series of right cyclic-shifts to the respective generator row. Note that each of the circulants generated in this manner has a size of p×p.

At step 408, the nk circulants generated at step 406 are arranged to form a rectangular array having k block rows and n block columns, e.g., as shown in Eq. (2). This rectangular array of circulants is a candidate matrix, B_{c}. In one embodiment, each of the circulants located in a block row of B_{c} is different from any of the other (n-1) circulants located in the same block row.

At step 410, candidate matrix B_{c} is evaluated to check if it satisfies the following criteria:

(i) the minimum distance of B_{c} is greater than L₁;

(ii) the number of minimum codewords that B_{c} has is smaller than L₂; and

(iii) the number of minimum near-codewords that B_{c} has is smaller than L₃.

The minimum codewords and minimum near-codewords of B_{c} may be catalogued during the evaluation.

If criteria (i)-(iii) are satisfied, then the processing of method 400 is directed to step 412. Otherwise, the processing of method 400 is directed back to step 404. Several different candidate matrices B_{c} may have to be iteratively tried before the processing of method 400 can continue on to step 412. However, due to the relatively small size of each candidate matrix B_{c}, the processing loop comprising steps 404-410 takes a relatively short time, which enables method 400 to be relatively time-efficient.

At step 412, candidate matrix B_{c} is pronounced to be an acceptable proxy-generator matrix B, and the processing of method 400 is terminated.

FIG. 5 shows a flowchart of a machine-based (e.g., computer-aided) method 500 of estimating performance (e.g., error-rate) characteristics of a read channel according to another embodiment of the disclosure. Similar to method 300, method 500 can be implemented as an add-on or plug-in module for a more-general computer-aided design and simulation tool. Method 500 can be embodied in the form of program code, stored in a non-transitory computer-readable storage medium such that, when the program code is loaded into and executed by a computer, the computer becomes an apparatus for carrying out method 500.

As mentioned above, a good quasi-cyclic parity-check matrix suitable for use in the LDPC decoder of a practical read channel is usually characterized by (i) an SFR-versus-SNR curve that has a very steep waterfall region and a very low error-floor level and (ii) a very low rate of miscorrection. These characteristics make it very difficult to obtain, by direct simulation, usable quantitative estimates of the error-floor level and/or the rate of miscorrection corresponding to relatively high SNR values typical for modern read channels. Method 500 addresses this problem by relying on an ad hoc heuristic error-rate estimation tool instead of direct simulation. After being constructed, the heuristic error-rate estimation tool is subjected to verification using a proxy matrix H′ (FIG. 3D).

In one embodiment, the verification procedure includes running a read-channel simulator and the heuristic error-rate estimation tool using proxy matrix H′ instead of parity-check matrix H and then comparing the respectively obtained performance characteristics. If both the read-channel simulator and the heuristic error-rate estimation tool produce substantially similar results for proxy matrix H′, then it is concluded that the heuristic error-rate estimation tool has been properly constructed and that its run for parity-check matrix H will produce relatively accurate estimates of the performance characteristics of the corresponding configuration of the read channel. Since heuristic error-rate estimation methods are significantly less computationally intensive than direct simulations, the estimates for parity-check matrix H can advantageously be obtained in a relatively short period of time.

At step 502 of method 500, a parity-check matrix H for which the performance characteristics of the read channel need to be evaluated is received or selected.

At step 504, parity-check matrix H is modified to generate a corresponding proxy matrix H′. In one embodiment, step 504 includes the sub-steps of: (i) generating a proxy-generator matrix B, e.g., using method 400 (FIG. 4); (ii) generating a corresponding proxy matrix H′ based on parity-check matrix H and proxy-generator matrix B, e.g., using the processing analogous to that of step 304 in method 300 (FIG. 3A); and (iii) verifying that proxy matrix H′ meets specified criteria, e.g., using the processing analogous to that of step 306 in method 300 (FIG. 3A).

At step 506, the read-channel simulator is run using proxy matrix H′ as the parity-check matrix, e.g., using the processing analogous to that of step 310 in method 300 (FIG. 3A). Exemplary simulation results of step 506 may look similar to the data shown in FIG. 1 and/or FIG. 2.

At step 508, an ad hoc heuristic error-rate estimation tool is constructed or configured for obtaining quantitative estimates of the pertinent performance characteristics of the read-channel.

As used herein, the term “heuristic” refers to a technique designed for solving a problem more quickly when alternative, more-rigorous methods are too slow and/or for finding an approximate solution when alternative, more-rigorous methods fail to find a solution. The end result may be achieved by trading optimality, completeness, accuracy, and/or precision for speed. For example, one objective of a heuristic can be to produce a solution that is good enough for solving the problem at hand. This solution may be an approximate solution, but it is valuable because finding it does not require a prohibitively long time. Heuristics may produce results by themselves or be used in conjunction with other algorithms.

In one embodiment, a heuristic algorithm may rely on approximate theoretical constructs and/or incomplete sampling of the system under test. For example, a paper by Chad A. Cole, Eric K. Hall, Stephen G. Wilson, and Thomas R. Giallorenzi, entitled “A General Method for Finding Low Error Rates of LDPC Codes,” submitted for publication to the IEEE on Feb. 1, 2008, discloses a heuristic method of estimating the error floor of an LDPC code. The act of encoding this method for machine-based execution is an example of constructing an ad hoc heuristic error-rate estimation tool in step 508. The aforementioned paper by Cole et al. is incorporated herein by reference in its entirety.

In another embodiment, the heuristic error-rate estimation tool invoked at step 508 may be based on an execution-ready library of callable subroutines and/or program modules that can be called in a selected sequence, e.g., specified using a scripted macro, to generate an error-rate estimate for the read channel at the end of said sequence. The macro may also specify how the relevant data files are transferred/shared between the various called units. In this case, the act of running the macro is an example of configuring an ad hoc heuristic error-rate estimation tool in step 508.

At step 510, the heuristic error-rate estimation tool constructed or configured at step 508 is run using proxy matrix H′ as the parity-check matrix. Representative estimates generated at the end of step 510 may look similar to the data shown in FIG. 1 and/or FIG. 2.

Step 512 serves to redirect the subsequent processing of method 500 based on the results obtained at steps 506 and 510. If the results of steps 506 and 510 match to within an acceptable margin of discrepancy, then it is concluded that the heuristic error-rate estimation tool has been verified and the processing of method 500 is directed to step 514. Otherwise, the processing of method 500 is directed back to step 508, where appropriate adjustments can be made to the heuristic error-rate estimation tool. As used herein, the terms “adjustment” and “adjusting” should be construed to encompass at least some of the following procedures: (i) constructing a new heuristic error-rate estimation tool, e.g., de novo; (ii) changing at least some of the program code in at least one subroutine or program module of the existing heuristic error-rate estimation tool; (iii) adding a new subroutine or program module to the existing heuristic error-rate estimation tool; and (iv) changing a macro that configures the existing heuristic error-rate estimation tool. Several processing loops involving steps 508-512 may have to be run before the heuristic error-rate estimation tool is verified and the processing of method 500 can continue on to step 514.

At step 514, the verified heuristic error-rate estimation tool is run again, but now using the original parity-check matrix H of step 502. The verification procedure of the preceding processing steps in method 500 advantageously confers high degree of confidence upon the conclusion that the error-rate estimates generated at step 514 are a sufficiently accurate prediction of the expected performance characteristics of the actual physical read channel configured to use the parity-check matrix of step 502.

FIG. 6 shows a block diagram of a communication system 600 having a write channel 602 and a read channel 604 that can be designed using an embodiment of the disclosure. Disposed between write channel 602 and read channel 604 is a storage medium 640 (e.g., a flash drive, a hard-drive platter, etc.) configured to receive data from the write channel for storage therein and make the stored data available for retrieval through the read channel. System 600 has a system controller 650 that controls the operations of write channel 602, read channel 604, and storage medium 640.

In one embodiment, write channel 602 comprises a data source (e.g., input port) 610, an LDPC encoder 620, and a write processor 630. In operation, data source 610 provides a set of bits 612, often referred to as an original information word, to LDPC encoder 620. LDPC encoder 620 encodes original information word 612 using an LDPC code to generate an original codeword 622, often referred to as the channel-input codeword. Original codeword 622 is supplied to write processor 630, which converts it into an appropriate write signal 632 and applies the write signal to storage medium 640. Write signal 632 controllably alters the state of storage medium 640, thereby causing original codeword 622 to be stored in the storage medium.

In one embodiment, read channel 604 comprises a channel detector 660, a decoding and post-processing (DPP) unit 670, and a data destination (e.g., output port) 680. To retrieve original codeword 622 from storage medium 640, channel detector 660 senses the corresponding location(s) in the storage medium to obtain a read signal 642. Channel detector 660 then converts read signal 642 into a corresponding set of log-likelihood-ratio (LLR) values 662 and supplies said LLR values to DPP unit 670.

For example, an LLR value may comprise (i) a sign bit that represents the detector's best guess (hard decision) regarding the bit value stored at the corresponding sensed location in storage medium 640 and (ii) one or more magnitude bits that represent the detector's confidence in the hard decision. For example, channel detector 660 may output each LLR value as a five-bit value, where the most-significant bit is the sign bit and the four least-significant bits are the confidence bits. By way of example and not limitation, a five-bit LLR value of 00000 indicates a hard decision of 0 with minimum confidence, while a five-bit LLR value of 01111 indicates a hard decision of 0 with maximum confidence. Intermediate values (e.g., between 0000 and 1111) of confidence bits represent intermediate confidence levels. Similarly, a five-bit LLR value of 10001 indicates a hard decision of 1 with minimum confidence, while a five-bit LLR value of 11111 indicates a hard decision of 1 with maximum confidence, wherein the binary value of 10000 is unused. Other numbers of bits and other representations of confidence levels may also be used.

DPP unit 670 performs LDPC decoding on LLR values 662, which, if necessary, is followed by the application of one or more post-processing methods. More specifically, DPP unit 670 is configured to apply post-processing methods when the LDPC-decoding process fails, meaning, e.g., that, after the maximum allotted number of iterations, the output word of the LDPC decoder (not explicitly shown in FIG. 6) still has one or more unsatisfied parity checks. Depending on the actual number of unsatisfied parity checks, DPP unit 670 might (1) send a request to channel controller 650 to have channel detector 660 reread the corresponding location(s) in storage medium 640 and then repeat the decoding process for the newly received LLR values 662 or (2) alter the input to the LDPC decoder and restart the LDPC iterations with the altered input, but without a reread.

DPP unit 670 typically uses the first option when the output vector of the failed LDPC decoder has a relatively large number (e.g., more than about sixteen) of unsatisfied parity checks. DPP unit 670 typically uses the second option when the output vector of the failed LDPC decoder has a relatively small number of unsatisfied parity checks. After the LDPC decoder converges on a valid codeword, DPP unit 670 converts this codeword into the corresponding original information word and directs said word, via an output signal 672, to data destination 680.

While this invention has been described with reference to embodiments, this description is not intended to be construed in a limiting sense.

Unless explicitly stated otherwise, each numerical value and range should be interpreted as being approximate as if the word “about” or “approximately” preceded the value of the value or range.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Embodiments of the invention can be manifest in other specific apparatus and/or methods. The described embodiments are to be considered in all respects as only illustrative and not restrictive. All changes that come within the meaning and range of equivalency of the claims are to be embraced within their scope.

A person of ordinary skill in the art would readily recognize that steps of various above-described methods can be performed by programmed computers. Herein, some embodiments are intended to cover program storage devices, e.g., digital data storage media, which are machine or computer readable and encode machine-executable or computer-executable programs of instructions where said instructions perform some or all of the steps of methods described herein. The program storage devices may be, e.g., digital memories, magnetic storage media such as magnetic disks or tapes, hard drives, or optically readable digital data storage media. The embodiments are also intended to cover computers programmed to perform said steps of methods described herein.

The description and drawings merely illustrate embodiments of the invention. Furthermore, all examples recited herein are principally intended expressly to be only for pedagogical purposes to aid the reader in understanding an embodiment of the invention and the concepts contributed by the inventor(s) to furthering the art, and are to be construed as being without limitation to such specifically recited examples and conditions. Moreover, all statements herein reciting embodiments of the invention, as well as specific examples thereof, are intended to encompass equivalents thereof.

The functions of the various elements shown in the figures, including any functional blocks labeled as “processors,” may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “computer,” “processor,” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non volatile storage. Other hardware, conventional and/or custom, may also be included.

It should be appreciated by those of ordinary skill in the art that any block diagrams herein represent conceptual views of circuitry representing one of more embodiments of the invention. Similarly, it will be appreciated that any flowcharts, flow diagrams, state transition diagrams, pseudo code, and the like represent various processes which may be substantially represented in computer readable medium and so executed by a computer or processor, whether or not such computer or processor is explicitly shown.

Although embodiments of the invention have been described herein with reference to the accompanying drawings, it is to be understood that embodiments of the invention are not limited to the described embodiments, and one of ordinary skill in the art will be able to contemplate various other embodiments of the invention within the scope of the following claims.

What is claimed is:

1. A method of predicting performance of a read channel, the method comprising:
(A) modifying a parity-check matrix having a set of trapping sets to generate a proxy matrix having an additional set of trapping sets;
(B) running a machine-implemented read-channel simulator, wherein a turbo decoder in the read-channel simulator is configured to use the proxy matrix for performing parity checks; and
(C) predicting, based on simulation results of step (B), the performance of the read channel for a configuration in which a turbo decoder in said read channel is configured to use the parity-check matrix for performing parity checks.

2. The method of claim 1, wherein step (A) comprises modifying the parity-check matrix, based on a proxy-generator matrix, to generate the proxy matrix, wherein:
the parity-check matrix comprises an array of first circulants, wherein each of said first circulants has a first size;
the proxy-generator matrix comprises an array of second circulants, wherein each of said second circulants has a second size smaller than the first size; and
the proxy matrix comprises:
a set of unmodified first circulants; and
a set of matrix blocks, each corresponding to a respective one of the first circulants, wherein at least some matrix elements have been replaced by matrix elements of a respective one of the second circulants.

3. The method of claim 2, wherein the proxy-generator matrix has one or more of the following properties:
the minimum distance of the proxy-generator matrix is greater than six;
the number of minimum codewords of the proxy-generator matrix is smaller than ten; and
the number of minimum near-codewords of the proxy-generator matrix is smaller than one hundred.

4. The method of claim 2, wherein:
no two of the first circulants are identical to one another; and
no two of the second circulants are identical to one another.

5. The method of claim 2, wherein step (A) further comprises generating each of said matrix blocks by:
replacing a generator row of the respective first circulant by a binary string formed by concatenating a generator row of the respective second circulant and a string of zeros; and
replacing P-1 subsequent rows of the respective first circulant by P-1 rows generated by subjecting the binary string to a series of circular shifts, where P is the first size.

6. The method of claim 2, wherein step (A) further comprises:
generating a set of binary strings using a random-number generator, wherein each of the binary strings in said set of binary strings is different from any of the other binary strings in said set of binary strings; and
generating each of the second circulants in a block row of the proxy-generator matrix by using a respective one of the binary strings from said set of binary strings as a generator row.

7. The method of claim 1, wherein step (C) comprises at least one of:
(C1) predicting an error rate of the turbo decoder; and
(C2) predicting a miscorrection rate of the turbo decoder.

8. The method of claim 1, wherein:
in step (B), the machine-implemented read-channel simulator is adapted to simulate a first configuration of the read channel; and
the method further comprises:
(D) running the machine-implemented read-channel simulator, wherein:
the turbo decoder in the read-channel simulator is configured to use the proxy matrix for performing parity checks; and
the machine-implemented read-channel simulator is adapted to simulate a second configuration of the read channel; and
(E) selecting, based on simulation results of steps (B) and (D), one of the first and second configurations for the read channel.

9. The method of claim 8, wherein the first configuration of the read channel and the second configuration of the read channel differ from one another in one or more of the following:
an applied decoding scheme;
a decoder type;
a scheme or architecture of the read channel; and
one or more of parameters of operation under a common scheme of the read channel.

10. The method of claim 1, further comprising:
(D) running a machine-implemented heuristic error-rate estimation tool for the proxy matrix; and
(E) comparing results of steps (B) and (D) to validate the machine-implemented heuristic error-rate estimation tool.

11. The method of claim 10, further comprising:
(F1) if the heuristic error-rate estimation tool is validated in step (E), then predicting the performance of the read channel by running the machine-implemented heuristic error-rate estimation tool for the parity-check matrix;
(F2) if the machine-implemented heuristic error-rate estimation tool is not validated in step (E), then adjusting the machine-implemented heuristic error-rate estimation tool; and
(G) repeating steps (D) and (E) with the adjusted machine-implemented heuristic error-rate estimation tool.

12. The method of claim 11, wherein said adjusting in step (F2) comprises one or more of:
constructing a replacement for the machine-implemented heuristic error-rate estimation tool;
changing at least some of program code in the machine-implemented heuristic error-rate estimation tool;
adding a new subroutine or program module to the machine-implemented heuristic error-rate estimation tool; and
changing a macro that configures the machine-implemented heuristic error-rate estimation tool for being run.

13. A non-transitory machine-readable medium, having encoded thereon program code, wherein, when the program code is executed by a machine, the machine implements a validated machine-implemented heuristic error-rate estimation tool of claim 10.

14. The method of claim 1, wherein the turbo decoder comprises a low-density parity-check decoder.

15. An integrated circuit fabricated based on results of step (C) of claim 1.

16. A non-transitory machine-readable medium, having encoded thereon program code, wherein, when the program code is executed by a machine, the machine implements a method of predicting performance of a read channel, the method comprising:
(A) modifying a parity-check matrix having a set of trapping sets to generate a proxy matrix having an additional set of trapping sets;
(B) running a machine-implemented read-channel simulator, wherein a turbo decoder in the read-channel simulator is configured to use the proxy matrix for performing parity checks; and
(C) predicting, based on simulation results of step (B), the performance of the read channel for a configuration in which a turbo decoder in said read channel is configured to use the parity-check matrix for performing parity checks.

17. The non-transitory machine-readable medium of claim 16, wherein the method further comprises:
(D) running a machine-implemented heuristic error-rate estimation tool for the proxy matrix;
(E) comparing results of steps (B) and (D) to validate the heuristic error-rate estimation tool.

18. The non-transitory machine-readable medium of claim 17, wherein the method further comprises:
(F1) if the heuristic error-rate estimation tool is validated in step (E), then predicting the performance of the read channel by running the machine-implemented heuristic error-rate estimation tool for the parity-check matrix
(F2) if the machine-implemented heuristic error-rate estimation tool is not validated in step (E), then adjusting the machine-implemented heuristic error-rate estimation tool; and
(G) repeating steps (D) and (E) with the adjusted machine-implemented heuristic error-rate estimation tool.

19. The non-transitory machine-readable medium of claim 18, wherein said adjusting in step (F2) comprises one or more of:
constructing a replacement for the machine-implemented heuristic error-rate estimation tool;
changing at least some of program code in the machine-implemented heuristic error-rate estimation tool;
adding a new subroutine or program module to the machine-implemented heuristic error-rate estimation tool; and
changing a macro that configures the machine-implemented heuristic error-rate estimation tool for being run.

20. An apparatus for predicting performance of a read channel, the apparatus comprising:
means for modifying a parity-check matrix having a set of trapping sets to generate a proxy matrix having an additional set of trapping sets;
means for running a machine-implemented read-channel simulator, wherein a turbo decoder in the read-channel simulator is configured to use the proxy matrix for performing parity checks; and
means for predicting, based on results generated by the machine-implemented read-channel simulator, the performance of the read channel for a configuration in which a turbo decoder in said read channel is configured to use the parity-check matrix for performing parity checks.
